(19) United States
(12) Patent Application Publication
(10) Pub. No.: US 2014/0264634 A1
(43) Pub. Date: Sep. 18, 2014

(54) FINFET FOR RF AND ANALOG INTEGRATED CIRCUITS

(71) Applicant: INTERMOLECULAR, INC., (US)

(72) Inventor: Mankoo Lee, Fremont, CA (US)

(73) Assignee: INTERMOLECULAR, INC., San Jose, CA (US)

(21) Appl. No.: 13/826,219

(22) Filed: Mar. 14, 2013

(51) Int. Cl. H01L 29/66; H01L 29/78

(52) U.S. Cl. CPC H01L 29/66818; H01L 29/7854
USPC 257/407; 438/163

(57) ABSTRACT

Methods for making a FinFET having reduced device mismatch and low-frequency noise are disclosed for RF/analog IC designs. A semiconductor fin is formed having a height between 2 and 6 times its width, atomically smooth sidewalls, and rounded active corners to minimize device variability. The fin is operable as a channel between a source and a drain. A first layer of SiO₂ is formed on the fin. A second layer of a high-κ dielectric is formed on the first layer. A third layer comprising a conductor is formed on the second layer. Ohmic contacts comprising a metal silicide or a thin dielectric layer are formed on source and drain. The fin is formed by anisotropic wet etching, and the rounded active corners are formed by sacrificial oxidation. The conductor is formed to be either amorphous or polycrystalline with a grain size varying by no more than ±10%.

### FIELD OF THE INVENTION

One or more embodiments of the present invention relate to methods of manufacture of semiconductor devices.

### BACKGROUND

The causes of device mis-matching (MM) and low-frequency noise (LFN) in three-dimensional transistors such as fin-shaped field effect transistors (FinFETs) can be traced to such factors as dopant fluctuations, channel surface scattering, and channel mobility variations. These problems need to be minimized for precise analog circuit design, especially in such applications as A/D converters, SRAM device matching, differential amplifier current mirrors, reference voltage regulators, etc. Low-frequency noise can also play an important role as a cause of phase noise increase in voltage control oscillators (VCOs). Methods of reducing MM and LFN in FinFET design are therefore important design goals.

For radio frequency integrated circuit (RFIC) design, LFN in VCOs can be important. Power amplifier designs can also have non-linearities where the signal-to-noise ratio increases compared to low noise amplifier (LNA) designs when V_{dd} decreases. Both MM and LFN can be improved by using a relatively wide device, but there can still be problems related to high power requirements, and a large semiconductor area may be needed causing an increase in parasitic effects.

Typically, the causes of device MM are found to be:
Random distribution of channel dopant number related to channel dopant clustering or to deviation from Poisson statistics,
Fluctuations of physical parameters from variations of gate oxide thickness (Tₒₓ) or permittivity and channel-to-interface charge or state,
Line and width variations due to gate poly-silicon and/or metal edge grains and photoresist edge roughness,
Miscellaneous other effects such as gate depletion associated with gate material grain size distribution, boron penetration depth into gate oxide, source-drain diffusion sheet resistance variation in strong inversion for short FETs, field-dependent mobility fluctuations, and insufficient annealing due to metal coverage.

Halo implant methods have been used to improve a short channel effect (SCE). Typically, ion implantation is used to increase the doping adjacent to the source and drain regions of an FET in a way that effectively extends the source and drain under the gate electrode but at some depth below the semiconductor substrate surface. However, the SCE does not scale solely with area based on Pelgrom's MM model (Pelgrom et al., “Transistor matching in analog CMOS applications,” IEEE Int. Electron Devices Meeting, 915-18, 1998), but does scale with width and surface roughness. Current FinFET technology does not normally use halo implantation. Other effects can still impact MM, including tied down metal line over the gate, fill shape pattern, and gate oxide antenna connection. Occasionally, effective layout techniques can used to minimize MM, for example, by employing the crosswise coupling and/or common centroid layout technique described by Lee et al. (“Cross-coupled CMOS transistor structure for high-frequency VCO design,” IEEE Electron Device Letters, 30(5), 532-34, 2009). However, there remain opportunities for additional improvement in MM for FinFETs.

Regarding LFN, the use of high-ic dielectrics common in all FETs at state-of-the-art dimensions has been linked to intrinsic sources of fluctuations (density of traps, granularity, local variation of the permittivity, etc.) particularly in FinFET devices. LFN can be also be related to a source/drain strain effect and channel orientation dependency. Possible LFN origins include:
Channel carrier number fluctuation due to the random trapping/detrapping processes of charges in the oxide traps near the Si—SiO₂ (or high-κ dielectric) interface (observed primarily in n-channel FETs),
Bulk mobility fluctuation due to the stochastic nature of carrier scattering events (observed primarily in p-channel FETs),
Some combination of the above: empirical models can be used to fit behavior for RF circuit design.

Fulde et al. (“Analog circuits using FinFETs: benefits in speed-accuracy-power trade-off and simulation of parasitic effects,” Adv. Radio Sci., 5, 285-90, 2007) describe various performance characteristics for analog circuits using FinFETs. They describe silicon-on-insulator (SOI) devices using fully depleted Si fins on a buried oxide (BOX). The fin is surrounded by the gate stack. Selective epitaxial growth (SEG) fills the gaps between gate and source/drain (S/D) regions and reduces the S/D contact resistance. According to Fulde et al., halo implants are not normally needed for a FinFET, because the devices show a lower SCE compared to a planar FET. The FinFETs exhibit higher Iₒₙ/I_{off}, higher Gₘ/G_{d}, and lower leakage current due to a higher tunneling barrier height from the use of a thin-film body at the drain.

FinFETs are therefore promising devices for use in the design of mixed-signal analog circuits. On the other hand, when used in logic circuits, these transistors can exhibit hysteresis due to possible charge trapping in the high-κ dielectric and self-heating due to the BOX layer.

However, adequate solutions for MM and LFN are not yet fully known for FinFETs. As pointed out by Baravelli et al. (“Impact of line-edge roughness on FinFET matching performance,” IEEE Trans. Electron. Devices, 54, 2466-74, 2007), one of major causes of MM is line-edge roughness, where the roughness of edges can have a magnitude that is a large fraction of feature size. Other factors include R_{S}/R_{D} variation related to source and drain contact formation and its SEG, gate misalignment, and fin surface roughness.

LFN is commonly caused by mobility fluctuation for p-type FinFETs and channel charge carrier trapping in gate dielectrics for n-type FinFETs. Malm et al., (“Low-frequency noise in FinFETs with PtSi Schottky-barrier source/drain contacts,” IEEE 21^{st} International Conference on Noise and Fluctuations, 135-38, 2011) proposed the use of Schottky-barrier source/drain (S/D) contacts based on platinum-silicide (PtSi) for low parasitic resistance and low barrier height which was tuned by means of segregation of implanted As or B. Also we can lower a possible pinned Schottky-barrier by inserting a thin dielectric layer for metal-insulator-semiconductor (MIS) S/D junction formation.

### SUMMARY OF THE INVENTION

Embodiments of the present invention disclose FinFETs having improved performance characteristics in the form of reduced MM and reduced LFN. Methods of making improved FinFETs are also disclosed. Accordingly, FinFETs are disclosed comprising a fin, a first layer on the fin comprising SiO₂, a second layer on the first layer comprising a high-κ dielectric layer, and a third layer on the second layer comprising a conductor. The fin comprises a semiconductor material and is operable as a channel between a source and a drain, and has a height between 2 and 6 times its width, atomically smooth sidewalls, and rounded active corners. In some embodiments, the surface of the fin is passivated with fluorine.

The first layer comprising SiO₂ can have a thickness between 0.1 nm and 0.4 nm. The second layer comprising a high-κ dielectric can be one or more of silicon oxynitride, silicon nitride, tantalum oxide, titanium oxide, zirconium oxide, hafnium oxide, aluminum oxide, lanthanum oxide, yttrium oxide, yttrium aluminate, lanthanum aluminate, lanthanum silicate, yttrium silicate, hafnium silicate, zirconium silicate, or doped alloys, undoped alloys, mixtures, or multilayers thereof. The third layer comprising a conductor can comprise TiN or TaSiN. In some embodiments, the conductor is amorphous or has a grain size varying by no more than ±10%. In some embodiments, electrical connections to the third layer are disposed on both sides of the fin. In some embodiments, a plurality of electrical connections to the third layer on each side of the fin.

In some embodiments, a substantially ohmic contact is disposed on the source and/or drain. The substantially ohmic contact can be a metal silicide comprising one or more of Ni, Er, Y, Au, W, Ti, Al, or Pt. The substantially ohmic contact can also be a dielectric layer sufficiently thin to allow electron tunneling, wherein the dielectric comprises one or more of TiO₂, SiN, or ZnO₂. In some embodiments, a work-function-adjustment layer is disposed on the source and/or drain. The work-function-adjustment layer can be a metal nitride, such as a nitride of Al, Ti, Ta, or W.

Methods for forming the improved FinFETs are disclosed. In some embodiments, a fin comprising a semiconductor, having a height between 2 and 6 times its width, and operable as a channel between a source and a drain, is formed having atomically smooth sidewalls and rounded active corners. The atomically smooth sidewalls can be formed using an anisotropic wet-etching process. The rounded active corners can be formed using sacrificial oxidation and wet cleaning. In some embodiments, the surface of the fin is passivated with fluorine.

A first layer of SiO₂ is formed on the fin. A second layer comprising a high-κ dielectric is formed on the first layer. A third layer on comprising a conductor is formed on the second layer. The third layer can be formed using sputtering or atomic layer deposition, so that the conductor is amorphous or has a grain size varying by no more than ±10%.

In some embodiments, a substantially ohmic contact is formed on the source and/or drain. The substantially ohmic contact can be a metal silicide comprising one or more of Ni, Er, Y, Au, W, Ti, Al, or Pt. The substantially ohmic contact can also be a dielectric layer sufficiently thin to allow electron tunneling, wherein the dielectric comprises one or more of TiO₂, SiN, or ZnO₂.

In some embodiments, a work-function-adjustment layer is formed on the source and/or drain, where the work-function-adjustment layer is operable to reduce the work function of the source and/or drain. The work-function-adjustment layer can be a metal nitride, such as a nitride of Al, Ti, Ta, or W.

### BRIEF DESCRIPTION OF THE DRAWINGS

FIG. 1 shows embodiments of a FinFET having rounded “active corners” in (A) a SOI FinFET and (B) a bulk FinFET.

FIG. 2 shows two views of a bulk FinFET cross section.

FIG. 3 shows a MM plot of one-standard-deviation variations of I_{d} vs. V_{G} in the saturation region for a typical n-channel FET.

FIG. 4 shows a LFN plot of 1/f noise behavior as a function of frequency in the linear region for a typical n-channel FET.

### DETAILED DESCRIPTION

Before the present invention is described in detail, it is to be understood that unless otherwise indicated this invention is not limited to specific semiconductor devices or to specific semiconductor materials. Exemplary embodiments will be described for three-dimensional transistors such as FinFETs made on silicon substrates, but other devices can also be fabricated using the methods disclosed. It is also to be understood that the terminology used herein is for the purpose of describing particular embodiments only and is not intended to limit the scope of the present invention.

It must be noted that as used herein and in the claims, the singular forms “a,” “and” and “the” include plural referents unless the context clearly dictates otherwise. Thus, for example, reference to “a layer” includes two or more layers, and so forth.

Where a range of values is provided, it is understood that each intervening value, to the tenth of the unit of the lower limit unless the context clearly dictates otherwise, between the upper and lower limit of that range, and any other stated or intervening value in that stated range, is encompassed within the invention. The upper and lower limits of these smaller ranges may independently be included in the smaller ranges, and are also encompassed within the invention, subject to any specifically excluded limit in the stated range. Where the stated range includes one or both of the limits, ranges excluding either or both of those included limits are also included in the invention. Where the modifier “about” or “approximately” is used, the stated quantity can vary by up to 10%. Where the modifier “substantially equal to” or “substantially the same” is used, the two quantities may vary from each other by no more than 5%.

### DEFINITIONS

The term “FinFET” as used herein refers to a fin-shaped field effect transistor, typically having feature sizes of less than 28 nm, which includes a semiconductor “fin” that extends the semiconductor region between the source and drain above the semiconductor substrate. Fins have a high aspect ratio wherein the height of the fin is 2 to 6 times the width (e.g., fin width=8 nm and fin height=32 nm for 16 nm node bulk-FinFETs), although the aspect ratio can vary depending on processes from a process optimization purpose. FinFETs can also include “Tri-gate” FETs, “Pi-gate” FETs and “Omega-gate” FETs.

The term “atomically smooth” as used herein refers to an rms surface roughness of {tilde under (<)}2.5 nm. As applied to a fin sidewall, the resulting fin has a standard deviation of fin thickness of substantially the same value as the rms surface roughness.

The term “active corner” as used herein refers to any corner of a fin structure under the gate oxide. Active corners can be “rounded” to ensure that the gate oxide thickness and gate electrode thickness are substantially the same in the region of the active corner as the corresponding thickness over planar surfaces of the fin structure.

The term “ohmic contact” as used herein refers to a contact wherein the contact resistance is constant, and current is linear with applied voltage across the contact. A “substantially ohmic contact” is one wherein there can be small deviations (less than 5%) from linearity.

There are no comprehensive solutions known to minimize device mismatch (MM) and low frequency noise (LFN) in FinFETs. Accordingly, there is a need for improved methods for making FinFETs for better analog circuit performance. Embodiments of the present invention disclose FETs having improved performance characteristics in the form of reduced MM and reduced LFN. Device structural features that can be modified to reduce MM and LFN are disclosed. Theoretical analyses of sources of MM and LFN are presented. Novel methods of making improved FinFETs are also disclosed.

Flicker noise or 1/f noise as LFN is also reduced, because the causes of flicker noise are similar to the causes of MM although flicker noise is caused predominantly variations in interface traps (ΔNᵢₜ) and channel mobility (Δμ). The improved device characteristics are based on the recognition that FinFET Vₜ variations and its interactions with MM and LFN can be described as follows:
Variations in gate work function and parasitic resistance can be a source of noise.
As metal gate grain size becomes comparable to gate length (L_{g}), work function-induced ΔVₜ is caused by variations in gate metal grain size.
ALD, PVD, or sputtering can provide better control of gate metal grain size.
Side wall spacer optimization and the use of NiSi can reduce Vₜ variations by reducing parasitic S/D contact resistance.
Multiple fin layouts can reduce ΔVₜ and fin patterning process (resisted or spaced) can affect ΔVₜ and static noise margin (ΔSNM) of a static random access memory (SRAM) cell.
ΔIₒₙ is the dominant cause of ΔVₜ, but other factors may also contribute.

Embodiments of the present invention provide novel methods for reducing MM and LFN by (1) using improved etching and cleaning methods to reduce fin surface roughness or channel interface roughness, (2) using improved fin-body corner rounding methods to reduce gate charging variation, (3) reducing grain size in the gate electrode material to minimize metal gate work function variations under conditions of mechanical stress, and (4) reducing source/drain (S/D) parasitic resistance by introducing a novel silicide and/or follow-up implantation technique for tuning contact barrier height. Since excessive LFN can result from thinner high-κ gate dielectric thickness, insertion of thin pure oxide at the channel-to-gate dielectric interface can also be useful after the passivation on the active silicon surface.

In some embodiments, practical wet chemistry methods and cleaning methods are disclosed for forming atomically smooth fin surfaces. Effective FinFET layout is provided, together with methods for reducing parasitic resistance in FinFET device applications for analog circuit and RFIC designs. In addition, a method of reducing flicker noise (a component of LFN) is provided comprising inserting an oxide interfacial layer between the fin and the high-ic dielectric.

Embodiments will be generally described for n-type FinFET structures, but analogous embodiments for p-type FinFETs will be apparent to one of ordinary skill. As noted in the Background section above, compared to planar FETs, an advantage of FinFETs is that no halo implantation is normally required. FinFETs also have a small threshold voltage (Vₜ) variability due to reduced random dopant fluctuation (RDF) because of the undoped channel. The short channel effect (SCE) is also reduced by the three-dimensional fin gate structure (again, compared to planar FETs). Variations in oxide thickness and RDF are negligible sources of MM, but charging into the gate oxide, and gate electrode work function variation can be significant sources of both MM and LFN of FinFET devices.

Accordingly, FinFETs are disclosed comprising a fin, a first layer on the fin comprising SiO₂, a second layer on the first layer comprising a high-κ dielectric layer, and a third layer on the second layer comprising a conductor. The first layer (of SiO₂) is 0.1-0.4 nm thick and provides reduced trap density at the surface of the second layer (high-κ dielectric). The fin comprises a semiconductor material. The fin is operable as a channel between a source and a drain. The fin has a height between 2 and 6 times its width, atomically smooth sidewalls, and rounded active corners. In some embodiments, the surface of the fin is passivated with fluorine. In some embodiments, one or more substantially ohmic contact is disposed on the source and/or drain. The FinFET can further comprise electrical connections to the third layer on both sides of the fin.

Methods for making a FinFET having reduced device MM and LFN are also disclosed. In some embodiments, a semiconductor fin is formed having a height of 2-6 times its width, atomically smooth surface on sidewalls, and rounded active corners. The fin can be formed by, for example, anisotropic wet etching, and the rounded active corners can be formed by, for example, sacrificial oxidation, as elaborated below.

A first (interfacial) layer of SiO₂ is formed on the fin. The first layer (of SiO₂) is 0.1-0.4 nm thick. A second layer of a high-κ dielectric is formed on the first layer. High-κ dielectrics that can be used are not particularly limiting, and can include one or more of silicon oxynitride, silicon nitride, tantalum oxide, titanium oxide, zirconium oxide, hafnium oxide, aluminum oxide, lanthanum oxide, yttrium oxide, yttrium aluminate, lanthanum aluminate, lanthanum silicate, yttrium silicate, hafnium silicate, zirconium silicate, and doped alloys, undoped alloys, mixtures, and/or multilayers thereof A typical high-κ dielectric material is HfO₂. High-κ dielectric materials typically have κ greater than about 25.

A third layer comprising a conductor is formed on the second layer. The conductor can formed to have reduced grain size (or no grain structure) compared to typical conductors formed by PVD. For example, the conductor can be formed to be either amorphous or polycrystalline with a grain size varying by no more than ±10%. Amorphous TaSiN having no grain structure can be formed by ALD or PVD. Other conductors formed by ALD can also exhibit significantly reduced grain size compared to their PVD-formed counterparts. Work function variations in the conductor are also reduced.

Substantially ohmic contacts comprising a metal silicide or thin dielectric layer can be formed between the contact electrode and the source or drain. The metal silicide of the ohmic contacts can be a silicide of Ni, Er, Y, Au, W, Ti, Al, or Pt. In some embodiments, a thin dielectric layer can serve as a Schottky-barrier layer and can be inserted between the contact electrode and S/D semiconductor junctions to form a metal-insulator-semiconductor (MIS) contact. The dielectric can be one of TiO₂, SiN, or ZnO₂. The dielectric layer is thin enough to allow tunneling of electrons.

A work-function-adjustment layer of a metal nitride can also be provided on the source/drain electrodes. The metal nitride can be a nitride of Al, Ti, Ta, or W. The work-function-adjustment layers can reduce the work function of the source and drain electrodes.

These and other improvements are discussed in greater detail below.

### Atomically Smooth Fin Sidewalls

Reactive Ion Etching (RIE) is a commonly used method for forming high aspect ratio structures having a dimension normal to the substrate surface greater than an in-plane dimension by a factor of three or four. However, fin structures made in this way tend to have surface waviness and irregularities with amplitudes that can be a significant fraction of the fin thickness, resulting in part from plasma damage from the RIE process.

Accordingly, in some embodiments, surface roughness can be reduced so that the sidewalls are “atomically smooth,” defined herein as having a one-sigma (rms) surface roughness of less than 3 nm. In order to provide negligible thickness variation in the gate dielectric layer (formed, for example, by atomic layer deposition (ALD), rounding of the active corner is also necessary as described below. The corner rounding also enables uniformity of the gate metal thickness at the corner. Together, these improvements in device fabrication can reduce both metal gate work-function variation (ΔΦₘ) and gate oxide charge variation, two significant sources of device MM.

Anisotropic wet etching can be used to provide atomically smooth fin sidewalls Anisotropic wet etching utilizes the wet etching reaction of Si as follows: Si+4OH⁻→Si(OH)₄+4e⁻. A typical wet etchant solution comprises KOH or tetramethylammonium hydroxide (TMAH). The (111) plane of Si is stable in these solutions and (111) planes can therefore act as an etch stop, while, for example (100) and (110) planes are being etched. (See, for example, “Wet etching of silicon,” 2012 brochure from MicroChemicals GMBH, Ulm, Germany [available at www.microchemicals.eu/technical_information/silicon_etching.pdf], incorporated herein by reference). As applied to FinFETs, Liu et al. showed that “nano” [anisotropic] wet etching of (110)-oriented SOI wafers using orientation-dependent wet etching produced atomically smooth fin sidewalls, with σT_{Si} reduced from 3.5 nm to 2.5 nm (Liu et al. “Variability Analysis of Scaled Poly-Si Channel FinFETs and Tri-Gate Flash Memories for High Density and Low Cost Stacked 3D-Memory Application,” European Solid-State Device Research Conference (ESSDERC), 2011, incorporated herein by reference).

Electrodes formed on the smooth fin sidewalls can also exhibit uniform crystal orientation ultimately reducing the variability in the electrode work function with corresponding reduction in MM and LFN (further improved by depositing the electrode layers by ALD as noted below).

### Rounding of Active Corners

FIG. 1 shows embodiments of a FinFET having rounded “active corners” in (A) a SOI FinFET and (B) a bulk FinFET. Any corners 102 on the fin 101 that are under the gate electrode are referred to as “active” corners. The gate electrode 103 is on the gate high-κ dielectric layer 100 which forms the gate oxide in silicon-on-insulator (SOI) and bulk FinFETs as show in FIGS. 1A and 1B. Rounding the active corners can reduce the variability of the “weak-inversion” current I_{d} or sub-threshold leakage that occurs when the gate-source voltage is below Vₜ. The corner rounding can also reduce a possible abnormal sub-threshold slope variation. The reduced variability reduces MM, in part by reducing the trap density. In particular, the rounding reduces variability of the gate oxide thickness in the vicinity of the active corners. The rounding also reduces variability in the thickness of the gate electrode over the oxide.

In some embodiments, the corner rounding can be achieved by using sacrificial oxidation on the fin surface combined with an additional wet cleaning step. A portion of the fin surface is oxidized, and then the oxide is etched completely away; the process can provide a rounded corner with minimal oxide charge variation (OCV).

### SiO₂ Interfacial Layer

High-κ dielectrics are typically used with FinFETs. However, as the dielectric thickness becomes thinner (thereby reducing LFN), a large variation of flicker noise can be a problem. In addition, there can be a significant density of traps at the interface between the dielectric and the semiconductor. Accordingly, in some embodiments, the trap density in a FinFET can be reduced by forming a first layer on the fin, wherein the first layer comprises pure SiO₂ (also called an interfacial layer). The interfacial layer reduces interface trap density, which is a significant source of LFN. LFN is caused mostly by channel mobility and interface trap variability. The first layer can be 0.1 to 0.4 nm of SiO₂. In some embodiments, the first layer is formed by atomic layer deposition (ALD) after cleaning bare silicon with deionized water. Oxygen-containing precursor gases such as O₂, O₃, or H₂O are used in the ALD reactor.

The interface between the SiO₂ and the fin surface can optionally be passivated with fluorine to improve reliability. Dangling bonds at the surface of the fin can be passivated, for example, by creating Si—F bonds which are stable against atomic migration and can help to maintain a consistent and uniform equivalent oxide thickness for the gate oxide and interfacial layer. In some embodiments, the first layer is formed and passivation is done after formation of the sidewall spacers. Formation of sidewall spacers typically comprises forming a dummy gate structure from polycrystalline silicon, forming the sidewall spacers adjacent to the dummy gate on the fin surface, then etching away the dummy gate structure. In some embodiments, fluorine atoms for passivation are supplied from a fluorine containing plasma, for example, a plasma created from one or more of XeF₂, XeF₄, XeF₆, or NF₃. In some embodiments, plasma enhanced chemical vapor deposition (PECVD) is used to form the interface layer, and for the portion that is to include fluorine, a fluorine containing precursor gas such as CF₄ can be added.

### Reduced Gate Electrode Work-Function Variations

FIG. 2 shows two views of a FinFET. A side wall spacer 200 can be formed between the metal gate and the source 201 and drain 202 regions as shown in FIG. 2A. The gate electrode 206 is shown with grain boundaries 203, shown as white lines on black. The gate oxide 205 has an oxide thickness Tₒₓ. The arrows 208 show the oxide thickness Tₒₓ at rounded corners, substantially equal to the oxide thickness between the active corners. RDF is caused mainly by the variations of implanted dopant atoms 204 inside the fin, while OCV is responsible for trapped charge variation. The total variance in I_{d}, σ²(I_{d}), can be expressed by the sum of the products of sensitivities and variances of parameters:

$${σ}^{2} ( {I}_{d} ) = {\sum }_{j} {( \frac{\partial {I}_{d}}{\partial {p}_{j}} )}^{2} {σ}^{2} ( {p}_{j} ) \qquad ( 1 )$$

where pⱼε{ΔL_{g}, ΔW_{fin}, ΔH_{fin}, ΔTₒₓ, ΔR_{C}, ΔΦₘ, ΔNₐ}, where L_{g} is the length of the gate (along the fin), W_{fin} is the width of the fin, H_{fin} is the height of the fin, Tₒₓ is the thickness of the gate oxide, R_{c} is the contact resistance at the source and drain, Φₘ is the gate metal work function, and Nₐ is the acceptor atom concentration (for n-type FinFETs).

Gate electrodes are commonly deposited onto FinFETs using PVD. The resulting films are polycrystalline in structure with work function variations dependent on the variability of grain size and orientation. The work function variations, in turn, cause flat band voltage (V_{fb}) variations for short channel FinFETs. Both MM and LFN can be reduced if the work function variations can be minimized. Accordingly, in some embodiments, the gate electrode comprises polycrystalline TiN or TiAlN, or amorphous TaSiN. These materials can be deposited with a finer grain size compared to polycrystalline metals. The resulting ΔVₜ can be about 10-30 mV for capacitance oxide thickness (CET) of ˜2 nm, and the grain size of the conductor varies by no more than ±10%.

In some embodiments, atomic layer deposition (ALD) is used instead of PVD to form the gate electrodes, optionally followed by an annealing step, for example, using rapid thermal annealing (RTA). The use of ALD can provide better control over the gate electrode grain size, thereby minimizing Vₜ variations that can affect V_{fb}.

### Reduced Parasitic Resistance

The FinFET can include a substantially ohmic contact between the source and drain. In some embodiments, a Schottky-barrier layer can be formed between an electrode and at least one of the source and drain. The Schottky-barrier layer can comprise a metal silicide. The Schottky-barrier source/drain connections can be used to increase I_{d} and reduce ΔI_{d} at a given bias. In some embodiments, the Schottky-barriers comprise a metal silicide such as a silicide of Ni, Er, Y, Au, W, Ti, Al, or Pt, or mixtures thereof. Such connections result in reduced source and drain electrode resistance. In some embodiments, a thin dielectric layer can serve as a Schottky-barrier layer and can be inserted between the contact electrode and the S/D semiconductor to form a metal-insulator-semiconductor (MIS) contact. The dielectric can be one of TiO₂, SiN, or ZnO₂. The dielectric layer is thin enough to allow tunneling of electrons (a few nanometers, e.g., 1-3 nm). Work-function adjustment materials such as TiAlN, WN, or TaN can also be used to reduce parasitic resistance.

In some embodiments, gate electrode resistance can be further reduced by layout designs using gate connections from both sides of the fin, and more than one gate connection per side. All of these improved electrode connections can provide further reductions in MM and LFN. The multiple gate configuration is less sensitive to fin pattern density and metal interconnect scheme compared to a single gate configuration.

### Theoretical Basis of Reductions in MM and LFN

Without being bound by theory, a theoretical understanding of the sources of MM and LFN can be used to elucidate experimental approaches that can be fruitful for improving FinFET devices. For n-FETs in the saturation region (V_{G}−Vₜ>V_{D}), variations in performance can be taken to come from either random dopant fluctuations or variations in physical dimensions. Random dopant fluctuations cause variations in Vₜ with charge variation (ΔQ_{B}) within the depleted region and gate capacitance variation (ΔCₒₓ):

ΔVₜ∝ΔQ_{B}/ΔCₒₓ. (2)

Variations in the gain factor β can be expressed in terms of variations in gate width W, length L:

$$Δ β ∝ \frac{Δ W}{Δ L} Δ μΔ {C}_{ox} \qquad ( 3 )$$

where μ is the channel carrier mobility. The drain current is given by

$${I}_{d} = \frac{β}{2} {( {V}_{GS} - {V}_{t} )}^{2} . \qquad ( 4 )$$

The variance σ_{I}_{_{D}}² of the drain current can be expressed in terms of the variances of gain factor β and threshold voltage Vₜ:

$${σ}_{{I}_{d}}^{2} = {( \frac{\partial {I}_{D}}{\partial β} )}^{2} {σ}_{β}^{2} + {( \frac{\partial {I}_{d}}{\partial {V}_{t}} )}^{2} {σ}_{{V}_{t}}^{2} . \qquad ( 5 )$$

Using (3) in (4), one obtains

$${( \frac{{σ}_{{I}_{d}}^{2}}{{I}_{d}} )}^{2} = {( \frac{{σ}_{β}}{β} )}^{2} + {( \frac{2 {σ}_{{V}_{t}}}{{V}_{GS} - {V}_{t}} )}^{2} . \qquad ( 6 )$$

Applying the statistical relationship σ_{I}_{_{D}}=\sqrt{2}(ΔI_{d}), the mismatch relationship can be written as

$${σ}^{2} ( \frac{Δ {I}_{d}}{{I}_{d}} ) = {σ}^{2} ( \frac{Δ β}{β} ) + \frac{4}{{( {V}_{GS} - {V}_{t} )}^{2}} {σ}^{2} ( Δ {V}_{t} ) . \qquad ( 7 )$$

FIG. 3 shows a device MM plot of one-standard-deviation variations of ΔI_{d} vs. V_{G} in the saturation region for a typical n-channel FET. For low values of V_{G}, a higher MM is observed due to such causes as random dopant fluctuations, fixed trap charges, granularity of the gate electrode, and line edge roughness. However, for high V_{G}, MM is significantly reduced, and channel mobility is the primary source of MM.

Turning to LFN, following Hung et al., (“A unified model for the flicker noise in metal-oxide-semiconductor field-effect transistors,” IEEE Trans. Electron Devices, 37(3), 654-65, 1990), I_{d} can be expressed as

I_{d}=WμqNEₓ (8)

(Hung eqn. (26)), where q is the electron charge, N is the carrier density, and Eₓ is the horizontal channel electric field. The local variation in I_{d} can be expressed as

$$\frac{δ {I}_{d}}{{I}_{d}} = - [ \frac{1}{Δ N} \frac{δ Δ N}{δ Δ {N}_{t}} \pm \frac{1}{μ} \frac{δ μ}{δ Δ {N}_{t}} ] δ Δ {N}_{t} \qquad ( 9 )$$

(Hung eqn. (2)). Comparing (8) and (6), some similarity can be seen. Fluctuations in mobility and Nₜ can cause fluctuations in Vₜ by trapping/detrapping at the interface or in the gate oxide.

The gate-voltage-referred noise spectral density can be expressed by

S_{V}_{_{G}}=S_{I}_{_{d}}/gm² (10)

The gate voltage dependency in the linear region is given in accordance with Erturk et al., (“Gate voltage dependence of MOSFET 1/f noise statistics,” IEEE Electron Device Letters, 28(9), 812-14, 2007) by

$${S}_{{V}_{G}} ( f ) = {\frac{{q}^{2} k T}{γ {WLC}_{ox}^{2} f} [ 1 + {α}_{SC} {μ}_{0} {C}_{ox} ( {V}_{G} - {V}_{t} ) ]}^{2} {N}_{t} \qquad ( 11 )$$

As with the MM shown in FIG. 3, similar LFN behavior can be seen in FIG. 4 in the linear region. In particular FIG. 4 shows that the measured 1/f noise as a function of frequency for an n-type FET is linear for conditions of 25° C., V_{D}=0.2 V, V_{G}=1.25 V (V_{S}=0). At frequencies above about 200 kHz, the noise is approximately constant and due primarily to thermal mobility fluctuations.

In summary, FIGS. 3 and 4 show some similarities (or correlations) in terms of line shapes and physical mechanisms between MM parameters in Vₜ and β variations and LFN behavior in Nₜ and μ fluctuations in the frequency domain. Accordingly, MM and LFN can be reduced simultaneously by optimizing gate-, insulator-, and channel-interface-related processes together as indicated by the equation (1).

For a large device, we can apply the evaluation of MM and LNF behaviors by Pelgrom's matching equation (for example, σ(Vₜ)=ΔVₜ/\sqrt{WL}). From Erturk et al. (op. cit.), the similarity of geometrical variations for LFN related parameter (Nₜ) can be seen:

$$\frac{σ {n}_{t}}{〈 {n}_{t} 〉} = \frac{\sqrt{{WLN}_{t}}}{{WLN}_{t}} = \sqrt{\frac{1}{{WLN}_{t}}} \qquad ( 11 )$$

Here Nₜ is considered as the random variable for LFN. For a larger device having larger W and L, Eqn. 11 shows that the trap variation can be reduced.

It will be understood that the descriptions of one or more embodiments of the present invention do not limit the various alternative, modified and equivalent embodiments which may be included within the spirit and scope of the present invention as defined by the appended claims. Furthermore, in the detailed description above, numerous specific details are set forth to provide an understanding of various embodiments of the present invention. However, one or more embodiments of the present invention may be practiced without these specific details. In other instances, well known methods, procedures, and components have not been described in detail so as not to unnecessarily obscure aspects of the present embodiments.

What is claimed is:

1. A method of making a FinFET comprising
forming a fin having atomically smooth sidewalls and rounded active corners,
forming a first layer on the fin, wherein the first layer comprises SiO₂,
forming a second layer on the first layer, wherein the second layer comprises a high-κ dielectric, and
forming a third layer on the second layer, wherein the third layer comprises a conductor,
wherein the fin comprises a semiconductor and has a height between 2 and 6 times its width, and
wherein the fin is operable as a channel between a source and a drain.

2. The method of claim 1, further comprising forming a substantially ohmic contact on the source or drain.

3. The method of claim 1, further comprising forming a work-function-adjustment layer on at least one of the source and drain, wherein the work-function-adjustment layer is operable to reduce the work function of the source or drain.

4. The method of claim 1, wherein the atomically smooth sidewalls are formed using an anisotropic wet-etching process.

5. The method of claim 1, wherein the rounded active corners are formed using sacrificial oxidation and wet cleaning.

6. The method of claim 1, wherein the third layer is formed using sputtering or atomic layer deposition, and wherein the conductor is amorphous or has a grain size varying by no more than ±10%.

7. The method of claim 1, further comprising passivating the surface of the fin with fluorine.

8. A FinFET comprising
a fin comprising a semiconductor material, the fin having a height between 2 and 6 times its width, atomically smooth sidewalls, and rounded active corners, and wherein the fin is operable as a channel between a source and a drain,
a first layer comprising SiO₂ formed on the fin,
a second layer comprising a high-κ dielectric layer formed on the first layer, and
a third layer comprising a conductor formed on the second layer.

9. The FinFET of claim 8, wherein the conductor is amorphous or has a grain size varying by no more than ±10%.

10. The FinFET of claim 8, further comprising a substantially ohmic contact on the source or drain.

11. The FinFET of claim 10, wherein the substantially ohmic contact comprises a metal silicide comprising one or more of Ni, Er, Y, Au, W, Ti, Al, or Pt.

12. The FinFET of claim 10, wherein the substantially ohmic contact comprises a dielectric layer sufficiently thin to allow electron tunneling, wherein the dielectric comprises one or more of TiO₂, SiN, or ZnO₂.

13. The FinFET of claim 8, wherein a work-function-adjustment layer is disposed on the source or drain.

14. The FinFET of claim 13, wherein the work-function-adjustment layer comprises a metal nitride.

15. The FinFET of claim 14, wherein the metal nitride comprises one or more of Al, Ti, Ta, or W.

16. The FinFET of claim 8, wherein the first layer has a thickness between 0.1 nm and 0.4 nm.

17. The FinFET of claim 8, wherein the high-κ dielectric comprises one or more of silicon oxynitride, silicon nitride, tantalum oxide, titanium oxide, zirconium oxide, hafnium oxide, aluminum oxide, lanthanum oxide, yttrium oxide, yttrium aluminate, lanthanum aluminate, lanthanum silicate, yttrium silicate, hafnium silicate, zirconium silicate, or doped alloys, undoped alloys, mixtures, or multilayers thereof.

18. The FinFET of claim 8, wherein the third layer comprises TiN or TaSiN.

19. The FinFET of claim 8, further comprising electrical connections to the third layer on both sides of the fin.

20. The FinFET of claim 18, further comprising a plurality of electrical connections to the third layer on each side of the fin.
